(19) United States
(12) Patent Application Publication
(10) Pub. No.: US 2006/0240622 A1
(43) Pub. Date: Oct. 26, 2006

(54) Multi-channel semiconductor device and method of manufacturing the same

(75) Inventors: Sung-young Lee, Yongin-si (KR); Eun-jung Yun, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/407,607

(22) Filed: Apr. 20, 2006

(30) Foreign Application Priority Data
Apr. 21, 2005 (KR) 10-2005-0033200

(51) Int. Cl. H01L 21/336

(52) U.S. Cl. 438/257

(57) ABSTRACT

Provided are a multi-channel semiconductor device and a method for manufacturing the semiconductor device through a simplified process. A sacrificial layer and a channel layer are alternately stacked on a semiconductor substrate. Thereafter, the sacrificial layer and the channel layer are etched to form a separated active pattern, and a device isolation layer is formed to cover sidewalls of the active pattern. Dopant ions are implanted into the entire semiconductor substrate, thereby forming a channel separation region under the active pattern. A portion of the active pattern is etched to separate the active pattern from a pair of facing sidewalls of the device separation layer, thereby forming a channel pattern having a pair of first exposed sidewalls. Source/drain semiconductor layers are formed on the first sidewalls of the channel pattern, and a part of the device isolation layer is removed to expose a pair of second sidewalls of the channel pattern contacting with the device separation layer. Thereafter, the sacrificial layer included in the channel pattern is remove, and a conductive layer for a gate electrode is formed to cover the channel layer exposed by the removing of the sacrificial layer.

### CROSS-REFERENCE TO RELATED PATENT APPLICATION

This application claims the benefit of Korean Patent Application No. 10-2005-0033200, filed on Apr. 21, 2005, in the Korean Intellectual Property Office, the contents of which are incorporated herein in their entirety by reference.

### BACKGROUND OF THE INVENTION

1. Field of the Invention

The present invention relates to a semiconductor device, and more particularly, to a multi-channel CMOS transistor and a method of manufacturing the CMOS transistor through a simplified process.

2. Description of the Related Art

With the high integration of a semiconductor device, an active region of the semiconductor device is reduced in size and thus a channel of a MOS transistor formed in the active region is reduced in length. The reduced length of the channel causes a short channel effect, thereby increasing leakage current. Also, as the size and a driving voltage of the MOS transistor are reduced, its output current is reduced.

There have been proposed various MOS transistors that can provide improved performance while having reduced size. Examples of these MOS transistors are fin MOS transistors, fully depleted lean-channel transistor (DELTA) MOS transistors, and gate all around (GAA) MOS transistors. In the fin MOS transistor, a plurality of parallel channel fins are arranged between source/drain regions, a gate electrode is extended from the top surfaces and sidewalls of the channel fins, and gate control is performed at both sides of the channel fins. This fin structure results in the reduction of the short channel effect. However, the channel fins are arranged along a width direction of a gate, resulting in the increase of an area occupied by a channel region and the source/drain regions. Moreover, an increase in the number of channels results in the increase of a source/drain junction capacitance.

In the DELTA MOS transistor, an active layer with a predetermined width is vertically protruded, a gate electrode is formed to cover the active layer, and both sides of the active layer act as a channel layer. This DELTA structure prevents the short channel effect. However, when the DELTA MOS transistor is integrated on a bulk silicon substrate, the bulk silicon substrate is etched and oxidized so as to form the active layer. This oxidation process may separate the active layer from the substrate or may damage the active layer. Also, when the DELTA MOS transistor is integrated on a silicon on insulator (SOI) substrate, the width of the channel is restricted by the thickness of an insulating layer of the SOI substrate.

In the GAA MOS transistor, an active pattern is formed on the SOI substrate, and a gate electrode is formed to cover a channel region of the active pattern. This GAA structure also prevents the short channel effect as in the DELTA structure. However, when an insulating layer under an active pattern acting as source/drain regions and a channel region is etched using an undercut phenomenon of an anisotropic etching, not only the insulating layer under the active pattern acting as the channel region but also the insulating layer under the active pattern acting as the source/drain regions are etched. Accordingly, the gate electrode is formed under not only the channel region but also the source/drain regions, resulting in the increase of parasitic capacitance.

In order to solve the above problems, there has been proposed a multi-channel MOS transistor in which a plurality of horizontal channel layers are vertically stacked on a substrate and a gate electrode is formed to cover the channel layers. In the multi-channel MOS transistor, two epitaxial layers having different etch selectivity are repeatedly stacked on the substrate in turn, one of the two epitaxial layers is removed to form a plurality of horizontal channel regions, and the gate electrode is formed in the removed portion of the epitaxial layers. Accordingly, the occupation areas of the channel and source/drain regions can be decreased, thereby improving the integration degree of the device. Also, the parasitic capacitance can be reduced, thereby improving the operating speed of the transistor.

In general, a static RAM (SRAM) includes two pull-down devices, two pull-up devices, and two pass devices. The SRAM is classified into a full CMOS SRAM, a high load resistor (HLR) SRAM, and a TFT SRAM according to the structure of the pull-up devices. The full CMOS SRAM is widely used because of its low standby current, high-speed operation, and operational stability.

There has been proposed a method of fabricating the multi-channel CMOS transistor that is applied to the full CMOS SRAM with an increased integration degree and high-speed operation. In this method, p-type dopant ions and n-type dopant ions are implanted respectively into NMOS and PMOS transistor regions of a substrate to form a channel separation region, a plurality of horizontal channel layers are stacked on the substrate, and a gate electrode is formed to cover the horizontal channel layers. The channel separation region is formed by implanting high-concentration dopant ions with the same conductivity type as the substrate into the main surface of the substrate, and prevents the main surface of the substrate from acting as a channel layer for a transistor. At this point, the n-type dopant ions are implanted into the substrate surface on which the PMOS transistor is to be formed, and the p-type dopant ions are implanted into the substrate surface on which the NMOS transistor is to be formed.

Accordingly, when the conventional multi-channel CMOS transistor is formed on a bulk silicon substrate, n-type or p-type dopant ions are implanted into only a corresponding region of the substrate so as to form the channel separation region. This necessitates an alignment key for implanting the n-type and p-type dopant ions and a separate mask process for forming the alignment key, thereby complicating the fabricating process.

### SUMMARY OF THE INVENTION

The present invention provides a method of manufacturing a semiconductor device through a simplified process not requiring a separate mask process for ion implantation for channel separation.

The present invention also provides a semiconductor device manufactured by the above method.

According to an aspect of the present invention, there is provided a method for manufacturing a semiconductor device. In the method, a sacrificial layer and a channel layer are alternately stacked on a semiconductor substrate. The sacrificial layer and the channel layer are etched to form a separated active pattern, and a device isolation layer is formed to cover sidewalls of the active pattern. Dopant ions are implanted into the semiconductor substrate, thereby forming a channel separation region under the active pattern. A portion of the active pattern is etched to separate the active pattern from a pair of facing sidewalls of the device separation layer, thereby forming a channel pattern having a pair of first exposed sidewalls. Source/drain semiconductor layers are formed on the first sidewalls of the channel pattern, and a part of the device isolation layer is removed to expose a pair of second sidewalls of the channel pattern contacting with the device separation layer. Thereafter, the sacrificial layer included in the channel pattern is removed, and a conductive layer for a gate electrode is formed to cover the channel layer exposed by the removing of the sacrificial layer.

The channel layer may include a monocrystalline silicon layer epitaxially grown with the same material as the semiconductor substrate, and the sacrificial layer may include a monocrystalline germanium layer or a monocrystalline silicon-germanium layer that is epitaxially grown with material having a different etch selectivity than that of the channel layer. High-concentration dopant ions having the same conductivity type as the dopant ions implanted into the channel separation region may be implanted to further form a well during the forming of the channel separation region.

The source/drain semiconductor layer may include a monocrystalline silicon layer formed through a selective epitaxial process.

In one embodiment, the active pattern is etched during the forming of the channel pattern until a surface of the semiconductor substrate is exposed, and the device isolation layer is etched during the removing of a part of the device isolation layer until a surface of the semiconductor substrate is exposed.

According to another aspect of the present invention, there is provided a method for manufacturing a semiconductor device. In the method, a first active pattern and a second active pattern are formed on a semiconductor substrate, the first active pattern being separately formed and including a first sacrificial layer and a first channel layer that are alternately stacked, the second active pattern being separately formed and including a second sacrificial layer and a second channel layer that are alternately stacked. A device isolation layer is formed to cover sidewalls of the first active pattern and sidewalls of the second active pattern. Dopant ions are implanted into the semiconductor substrate, thereby forming a first channel separation region and a first well under the first active pattern and forming a second channel separation region and a second well under the second active pattern. A portion of the first active pattern and a portion of the second pattern are etched to separate the first and second active patterns from a pair of corresponding sidewalls of the device separation layer, thereby forming a first channel pattern having a pair of first exposed side walls and a second channel pattern having a pair of first exposed sidewalls. First source/drain semiconductor layers are formed on the first sidewalls of the first channel pattern, and second source/drain semiconductor layers are formed on the second sidewalls of the second channel pattern. A part of the device isolation layer is removed to expose a pair of second sidewalls of the first channel pattern and a pair of second sidewalls of the second channel pattern contacting with another pair of corresponding sidewalls of the device separation layer. The first and second sacrificial layers are removed. A first conductive layer for a gate electrode is formed to cover the first channel layer exposed by the removing of the first sacrificial layer, and a second conductive layer for a gate electrode is formed to cover the second channel layer exposed by the removing of the second sacrificial layer.

The forming of the first and second channel separation regions and the first and second well may include: forming a first photosensitive layer on the semiconductor substrate so that the first active pattern is exposed; implanting high-concentration dopant ions of a first conductivity type and low-concentration dopant ions of the first conductivity type into the semiconductor substrate by using the first photosensitive layer, thereby forming the first channel separation region and the first well under the first active pattern; forming a second photosensitive layer on the semiconductor substrate so that the second active pattern is exposed; and implanting high-concentration dopant ions of a second conductivity type and low-concentration dopant ions of the second conductivity type into the semiconductor substrate by using the second photosensitive layer, thereby forming the second channel separation region and the second well under the second active pattern.

The high-concentration dopant ions of the first conductivity type may be implanted at a predetermined energy and the low-concentration dopant ions of the first conductivity type are implanted at an energy higher than the predetermined energy, thereby forming the first well of low concentration and forming the first channel separation region of high concentration on the first well. The high-concentration dopant ions of the second conductivity type may be implanted at a predetermined energy and the low-concentration dopant ions of the second conductivity type are implanted at an energy higher than the predetermined energy, thereby forming the second well of low concentration and forming the second channel separation region of high concentration on the second well. The first channel separation region may be formed on the first well under the first channel layer and the first source/drain semiconductor layer, and the second channel separation region may be formed on the second well under the second channel layer and the second source/drain semiconductor layer.

The method may further include, before the first and second conductive layers: forming a first gate insulating layer between the first conductive layer and the first channel layer; and forming a second gate insulating layer between the second conductive layer and the second channel layer.

In one embodiment, the first and second channel layers include the same material as the semiconductor substrate, and the first and second sacrificial layers have a different etch selectivity than that of the first and second channel layers. In one embodiment, the first and second channel layers each includes an epitaxially-grown monocrystalline silicon layer, and the first and second sacrificial layers each include an epitaxially-grown monocrystalline germanium layer or an epitaxially-grown monocrystalline silicon-germanium layer.

In one embodiment, the method further comprises, before the forming of the first and second channel patterns, forming a first dummy gate and a second dummy gate on the first active pattern and the second active pattern, respectively, the first and second dummy gate each having a pad oxide layer, a nitride layer, and a high density plasma oxide layer stacked therein. The first active pattern and the second active pattern are etched by using the first dummy gate as a mask for the first active pattern and using the second dummy gate as a mask for the second active pattern, thereby forming the first channel pattern and the second channel pattern. In one embodiment, the etching of the first active pattern and the second active pattern for forming the first channel pattern and the second channel pattern is performed until a surface of the semiconductor substrate is exposed. The method can further include, before the removing of a part of the device isolation layer; forming an insulating layer on the semiconductor substrate to cover the first and second dummy gates; planarizing the insulating layer until the first and second dummy gates are exposed; and removing the first and second gates to expose the device separation layer contacting with a pair of the second sides walls of the first and second channel patterns. The exposed device separation layer is etched by using the insulating layer as a mask until the semiconductor substrate is exposed. The insulating layer can be a nitride layer.

In one embodiment, the first and second source/drain semiconductor layers include the same material as the first and second channel layers.

In one embodiment, the forming of the first and second source/drain semiconductor layers comprises: forming a first monocrystalline silicon layer on the first sidewalls of the first channel patterns and forming a second monocrystalline silicon layer on the first sidewalls of the second channel pattern by a selective epitaxial process; and implanting dopant ions of the second conductivity type and dopant ions of the first conductivity type into the first monocrystalline silicon layer and the second monocrystalline silicon layer, respectively.

According to a further aspect of the present invention, there is provided a semiconductor device including: a semiconductor substrate having a first well and a second well; a first channel region including a plurality of first channel layers separately stacked on the first well in a vertical direction with respect to a surface of the semiconductor substrate and a plurality of first tunnels disposed between the first channel layers, and a second channel region including a plurality of second channel layers separately stacked on the second well in a vertical direction with respect to the surface of the semiconductor substrate and a plurality of second tunnels disposed between the second channel layers; first source/drain regions on the first well contacting with a pair of first facing sidewalls of the first channel layers, and second source/drain regions formed on the second well contacting with a pair of first facing sidewalls of the second channel layers; a first gate electrode buried in the first tunnels and formed in a direction crossing a pair of second facing sidewalls of the first channel layers to cover the first channel layers, and a second gate electrode buried in the second tunnels and formed in a direction crossing a pair of second facing sidewalls of the second channel layers to cover the second channel layers; a first gate insulating layer formed between the first gate electrode and the first channel layers, and a second gate insulating layer formed between the second gate electrode and the second channel layers; and a first channel separation region formed on the first well under the first channel region and the first source/drain regions, and a second channel separation region formed on the second well under the second channel region and the second source/drain regions.

The semiconductor device may further include a device isolation layer formed to cover the first and second source/drain regions except for the first and second channel regions.

In one embodiment, the first channel separation region is a high-concentration dopant region having the same conductivity type as the first well, and the second channel separation region is a high-concentration dopant region having the same conductivity type as the second well, the first channel separation region having a conductivity type opposite to that of the second channel separation region.

In one embodiment, the first source/drain regions and the second source/drain regions include the same material as the first and second channel layers. In one embodiment, the first and second source/drain regions and the first and second channel layers include an epitaxially-grown monocrystalline silicon layer. In one embodiment, the first and second source/drain regions and the first and second channel layers include an epitaxially-grown monocrystalline silicon layer. In one embodiment, the first and second channel regions and the first and second source/drain regions are formed in the same plane on the semiconductor substrate.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a plan view of a CMOS transistor according to an embodiment of the present invention.

FIG. 2A is a sectional view taken along line A-A of FIG. 1.

FIG. 2B is a sectional view taken along line B-B of FIG. 1.

FIG. 3A through 3L are sectional views taken along line A-A of FIG. 1 to illustrate a method of manufacturing the CMOS transistor.

FIG. 4A through 4G are sectional views taken along line B-B of FIG. 1 to illustrate the method of manufacturing the CMOS transistor.

FIGS. 5A and 5B are respectively a characteristic curve of the CMOS transistor and a characteristic curve of a conventional CMOS transistor.

### DETAILED DESCRIPTION OF THE INVENTION

The present invention will now be described more fully with reference to the accompanying drawings, in which exemplary embodiments of the invention are shown. It will be understood that when a layer is referred to as being “on” another layer or substrate, it can be directly on the other layer or substrate, or intervening layers may also be present.

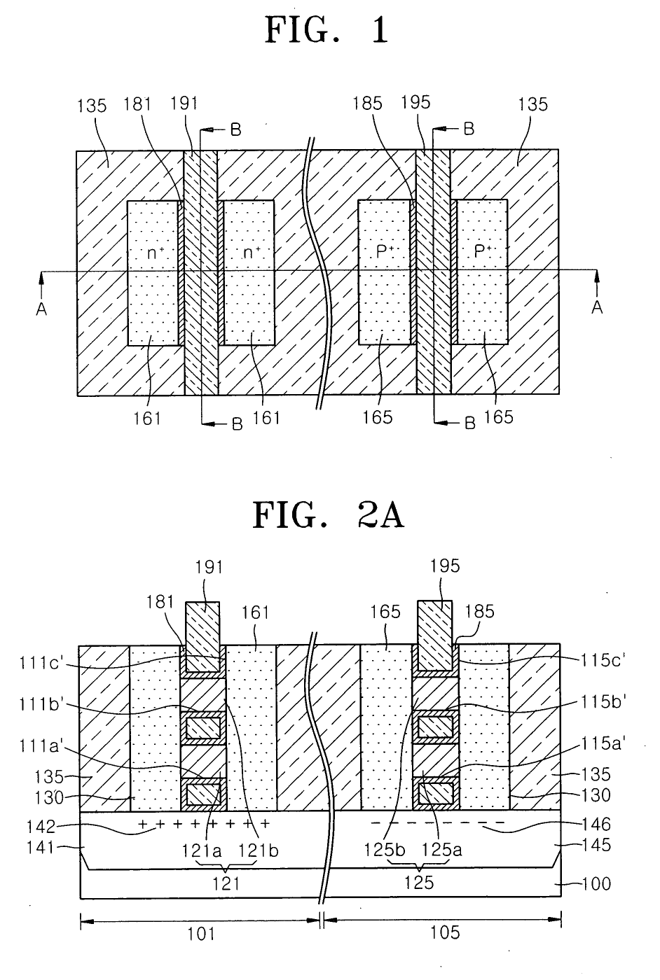

FIG. 1 is a plan view of a CMOS transistor according to an embodiment of the present invention. In FIG. 1, the left portion of the drawing corresponds to an NMOS transistor and the right portion of the drawing corresponds to a PMOS transistor.

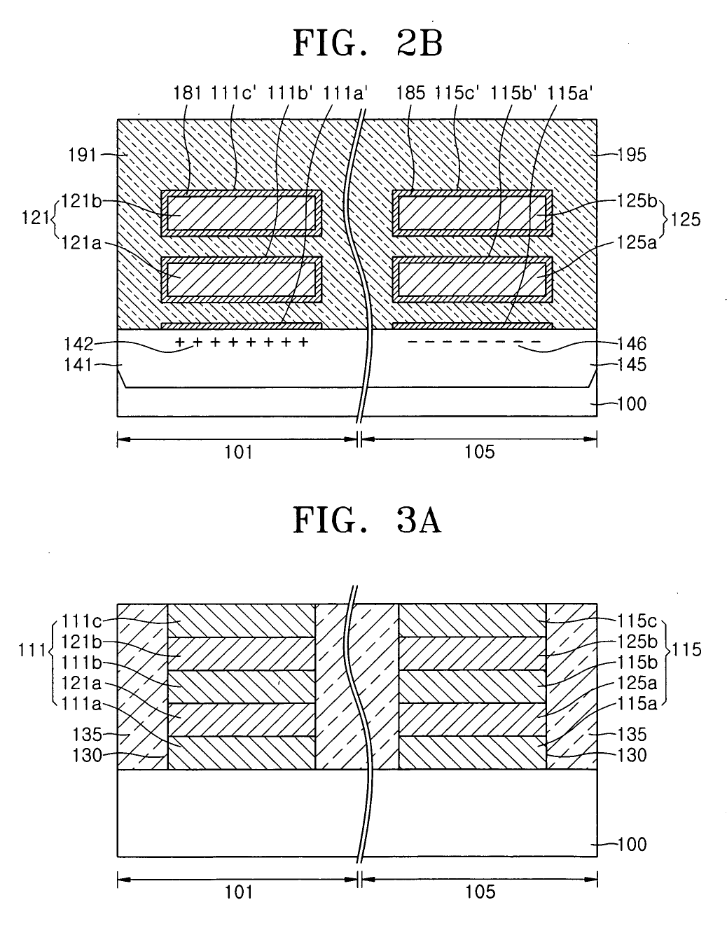

FIG. 2A is a sectional view taken along line A-A of FIG. 1, and FIG. 2B is a sectional view taken along line B-B of FIG. 1. In FIGS. 2A and 2B, the left portion of the drawings corresponds to an NMOS transistor and the right portion of the drawings corresponds to a PMOS transistor.

Referring to FIGS. 1, 2A and 2B, a semiconductor substrate 100 includes a first transistor region 101 in which an NMOS transistor is formed, and a second transistor region 105 in which a PMOS transistor is formed. A first well 141 of p⁻-type conductivity is formed in the first transistor region 101, and a second well 145 of n⁻-type conductivity is formed in the second transistor region 105. The superscript “+” represents that a well is heavily doped with dopants, and the superscript “−” represents that a well is lightly doped with dopants. A first channel region 121, which includes a plurality of first channel layers 121a and 121b arranged perpendicular to a main surface of the semiconductor substrate 100, is formed on the first well 101. Similarly, a second channel region 125, which includes a plurality of second channel layers 125a and 125b arranged perpendicular to the main surface of the semiconductor substrate 100, is formed on the second well 105.

A plurality of first tunnels 111a′ and 111b′ are formed between the first channel layers 121a and 121b, and a tunnel-shaped first groove 111c′ is formed on the uppermost first channel layer 121b. Likewise, a plurality of second tunnels 115a′ and 115b′ are formed between the second channel layers 125a and 125b, and a tunnel-shaped second groove 115c′ is formed on the uppermost second channel layer 125b. First source/drain regions 161 of n⁺-type conductivity are formed respectively at both sides of the first channel region 121 such that they are connected to the first channel layers 121a and 121b. Similarly, second source/drain regions 165 of p⁺-type conductivity are formed respectively at both sides of the second channel region 125 such that they are connected to the second channel layers 125a and 125b. The superscript “+” represents that a region is heavily doped with dopants, and the superscript “−” represents that a region is lightly doped with dopants. The number of the tunnels and the channel layers included in each of the first and second regions 121 and 125 should be considered in descriptive sense only and not for purposes of limitation. That is, the first and second channel regions 121 and 125 may include more than two tunnels and more than two channel layers.

A first gate insulating layer 181 is formed on an inner surface of each of the first tunnels 111a′ and 111b′ and the first groove 111c′, and a second gate insulating layer 185 is formed on an inner surface of each of the second tunnels 115a′ and 115b′ and the second groove 115c′. A first gate electrode 191 for the NMOS transistor is buried in the first tunnels 111a′ and 111b′ and the first groove 111c′ to cover the first channel layers 121a and 121b. Likewise, a second gate electrode 195 for PMOS transistor is buried in the second tunnels 115a′ and 115b′ and the second groove 115c′ to cover the second channel layers 125a and 125b. The first gate electrode 191 is arranged between the first source/drain regions 161 to intersect the first channel region 121 in the forming direction of the first source/drain regions 161. Similarly, the second gate electrode 195 is arranged between the second source/drain regions 165 to intersect the second channel region 125 in the forming direction of the second source/drain regions 165.

A trench 130 is formed to cover the first and second source/drain regions 161 and 165, except for the first and second channel regions 121 and 125, and a device isolation layer 135 is formed in the trench 130. A first channel separation region 142 is formed on a predetermined surface of the first well 141, which is defined below the first source/drain regions 161 and the first channel region 121. Likewise, a second channel separation region 146 is formed on a predetermined surface of the second well 145, which is defined below the second source/drain regions 165 and the second channel region 125. The first channel separation region 142 includes a p+ dopant region having the same conductivity type as the first well 141, thereby preventing the first well 141 under the lowermost first channel layer 121a from acting as a channel region of the NMOS transistor. Similarly, the second channel separation region 146 includes a n+ dopant region having the same conductivity type as the second well 145, thereby preventing the second well 145 under the lowermost first channel layer 125a from acting as a channel region of the PMOS transistor.

As described above, the first channel region 121 includes the first channel layers 121a and 121b covered by the first gate electrode 191, and the second channel region 125 includes the second channel layers 125a and 125b covered by the second gate electrode 195. Accordingly, when a gate voltage is applied to the first and second gate electrodes 191 and 195, channels are formed as many as the channel layers of the first and second channel regions 121 and 125. As a result, it is possible to increase a driving current from the NMOS and PMOS transistors formed respectively in the first and second wells 141 and 145.

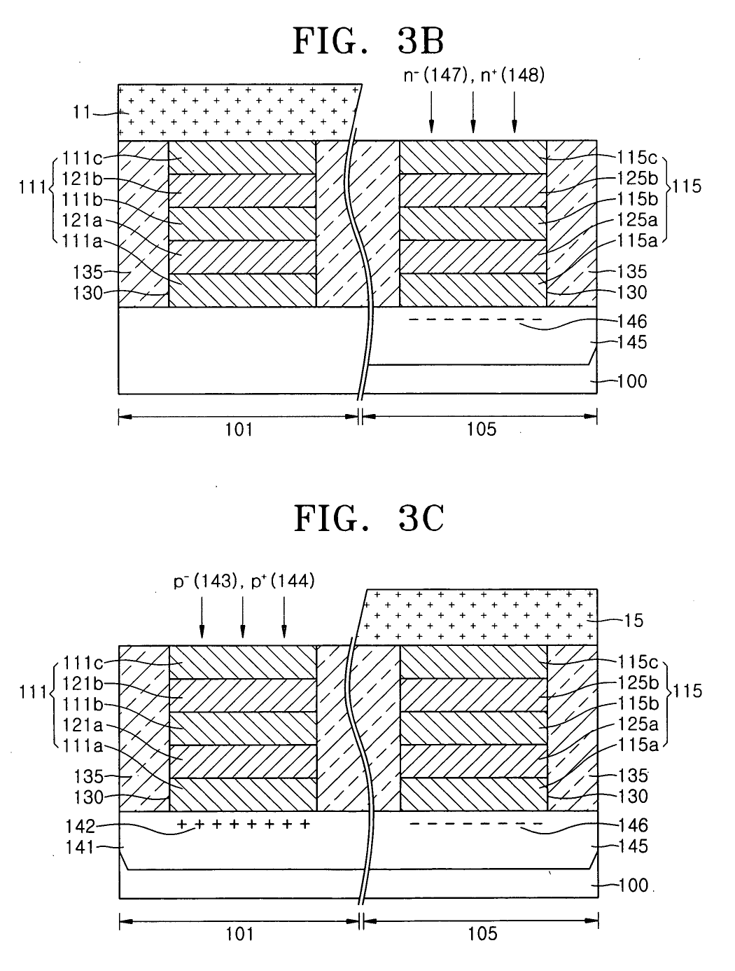

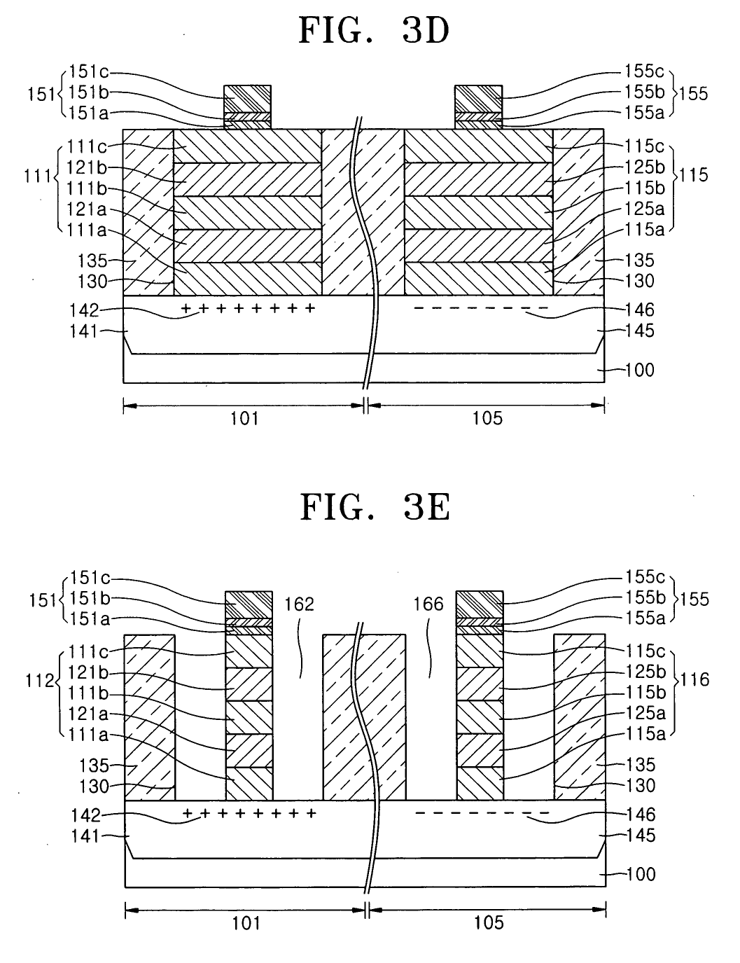

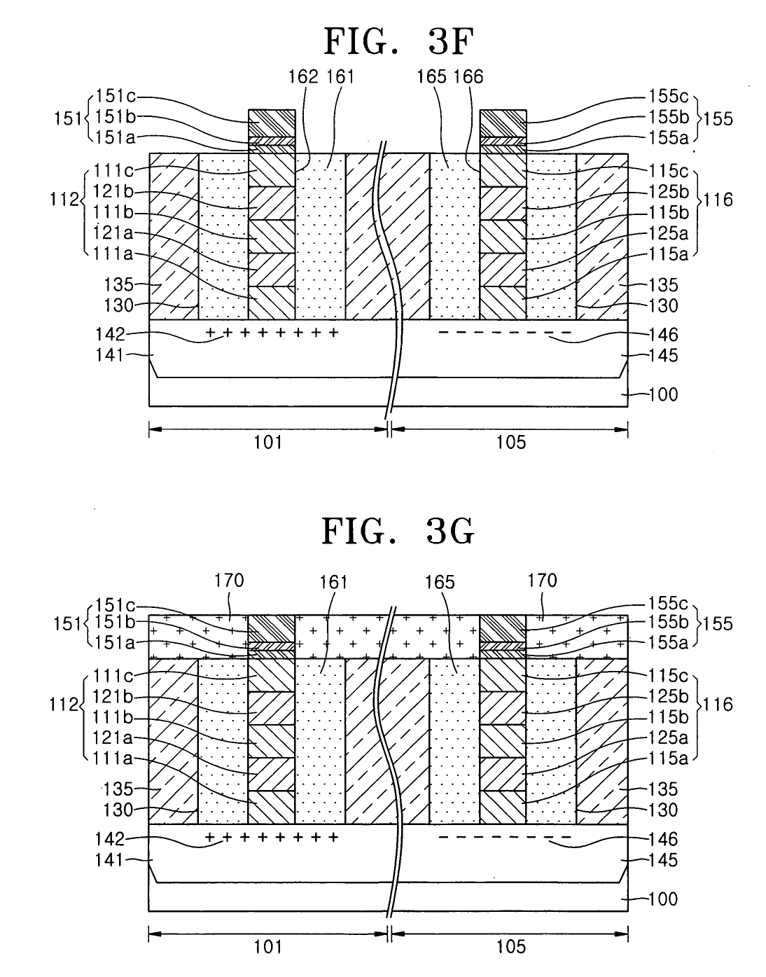

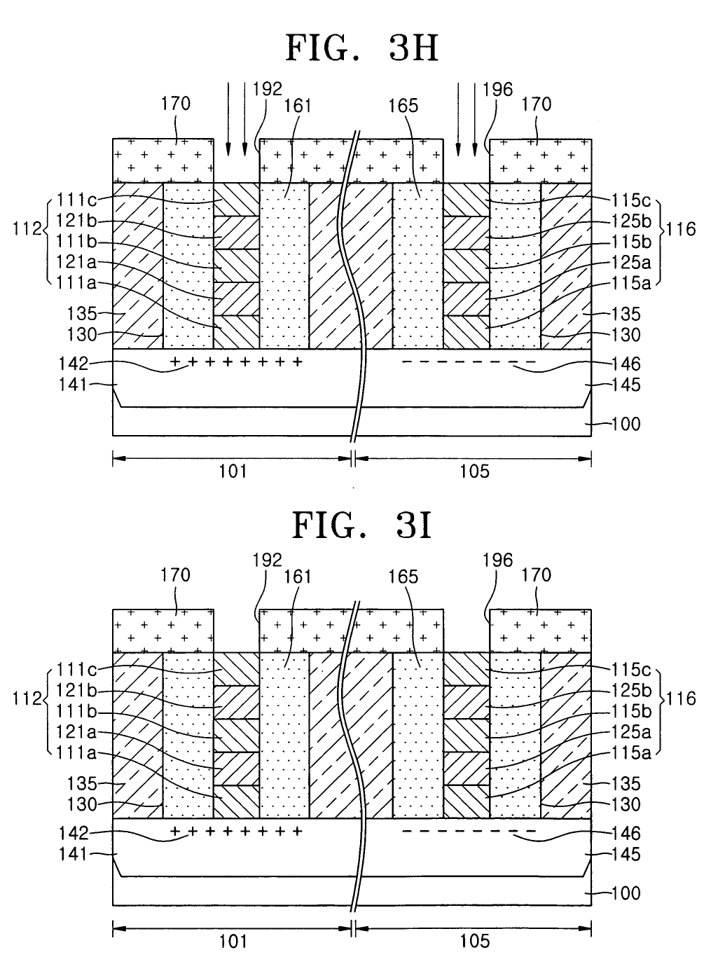

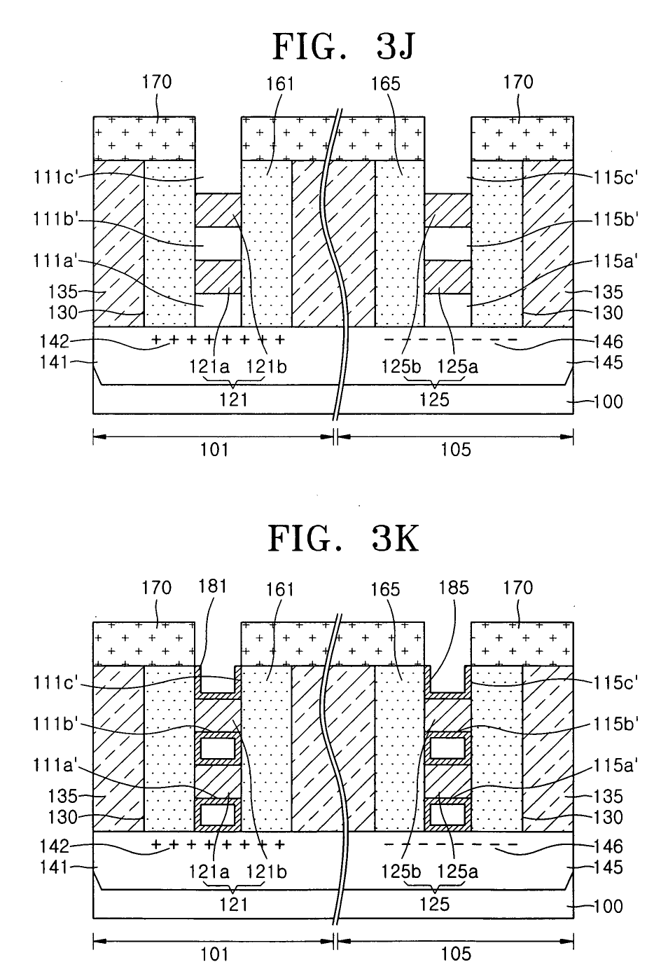

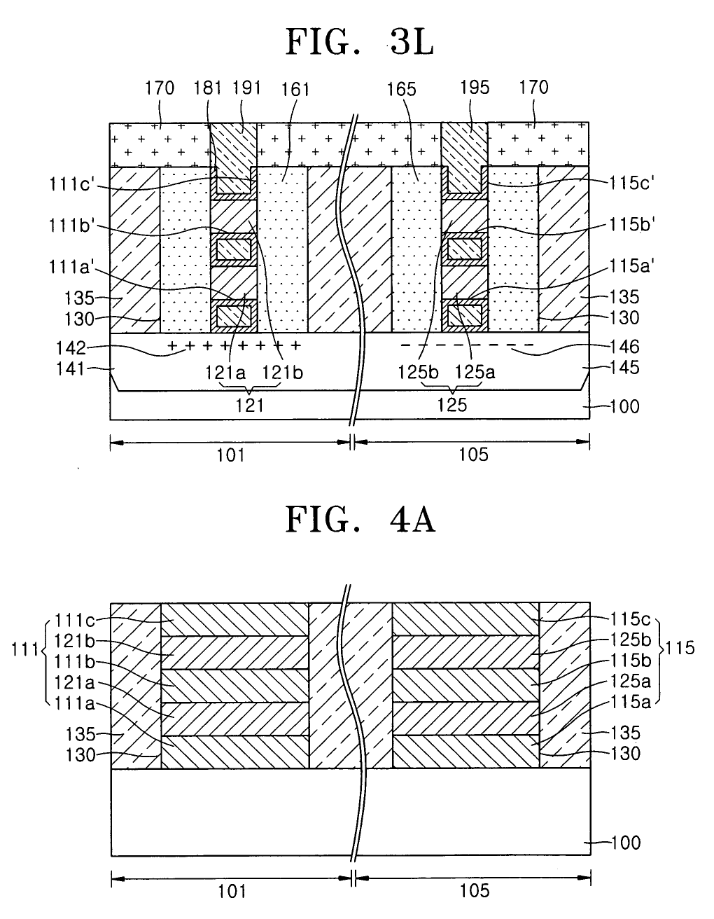

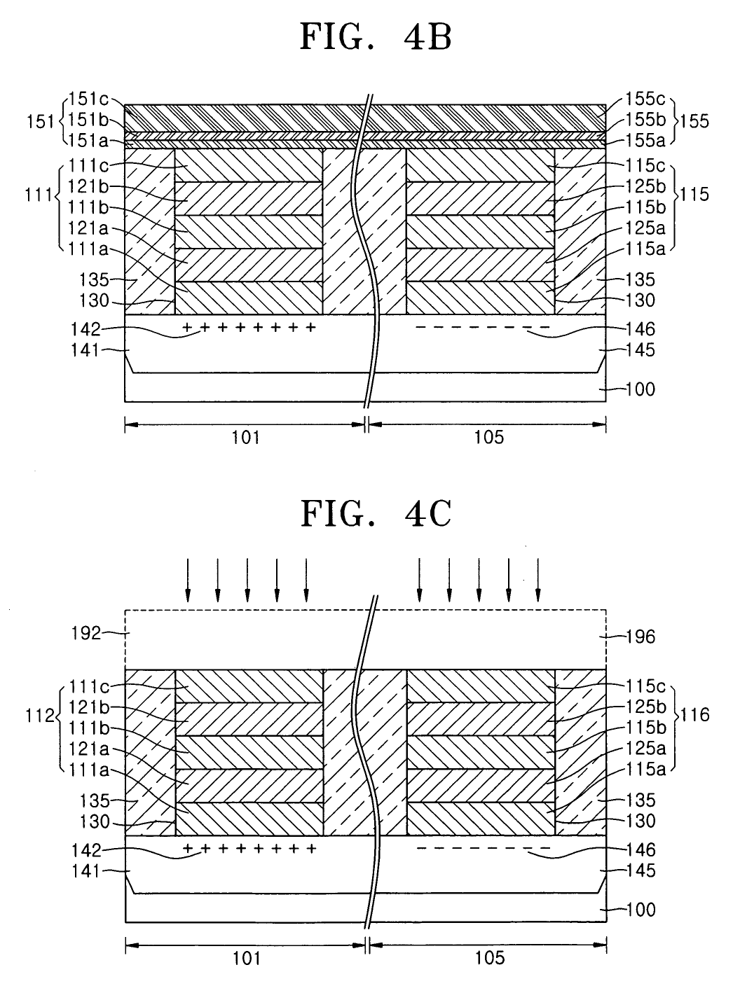

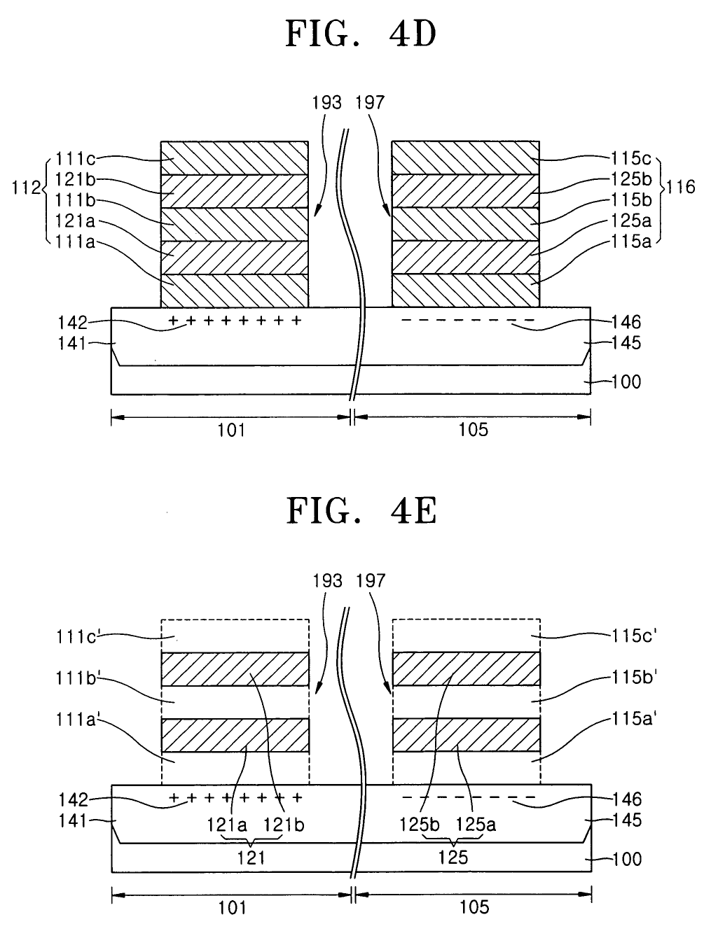

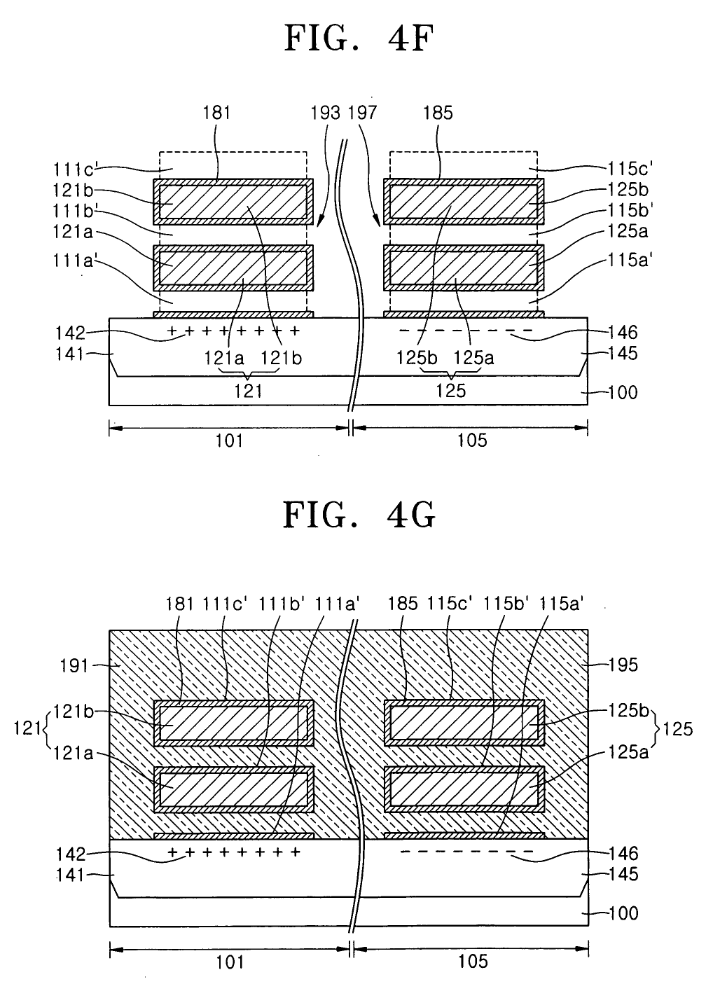

FIG. 3A through 3L are sectional views taken along line A-A of FIG. 1 to illustrate a method of manufacturing the CMOS transistor, which correspond to the sectional view illustrated in FIG. 2A. FIG. 4A through 4G are sectional views taken along line B-B of FIG. 1 to illustrate the method of manufacturing the CMOS transistor, which correspond to the sectional view illustrated in FIG. 2B. In FIGS. 3A through 3L and 4A through 4G, the left pportions of the drawings correspond to an NMOS transistor and the right portions of the drawings correspond to a PMOS transistor.

Referring to FIGS. 3A and 4A, a monocrystalline silicon semiconductor substrate 100 is prepared including first and second transistor regions 101 and 105 in which the NMOS transistor and he PMOS transistor are to be formed. First epitaxial layers 111a, 111b, 111c, 115a, 115b and 115c and second epitaxial layers 121a, 121b, 125a and 125b are repeatedly formed in turn on the first transistor region 101 and the second transistor region 105, respectively, thereby forming a stacked layer. The first epitaxial layers 111a, 111b, 111c, 115a, 115b and 115c have a different etch selectivity from the second epitaxial layers 121a, 121b, 125a and 125b. The first epitaxial layers 111c and 115c are disposed uppermost in the stacked layer. The number and thickness of the first and second epitaxial layers are determined according to a desired transistor.

The first epitaxial layers 111a, 111 b, 111c, 115a, 115b and 115c are removed in the following process to act as a sacrificial layer for forming tunnels in the channel region. The first epitaxial layers 111a, 111b, 111c, 115a, 115b and 115c are formed of material having a higher etch rate than that of the semiconductor substrate 100, and preferably includes a monocrystalline germanium layer or a monocrystalline silicon-germanium layer. The second epitaxial layers 121a, 121b, 125a and 125b include a monocrystalline silicon layer, and act as a channel layer of the channel region. Channel ions may be implanted during the stacking of the first epitaxial layers 111a, 111b, 111c, 115a, 115b and 115c and the second epitaxial layers 121a, 121b, 125a and 125b, or may be implanted into the stacked layer.

Thereafter, the stacked layer is selectively etched by photolithography to form a first active pattern 111 and a second active pattern 115 in the first transistor region 101 and the second transistor region 105, respectively. The first active pattern 111 includes the first epitaxial layers 111a, 111b and 111c and the second epitaxial layers 121a and 121b, and the second active pattern 115 includes the first epitaxial layers 115a, 115b and 115c and the second epitaxial layers 125a and 125b. A trench 130 is formed in the etched region of the stacked layer. During the forming of the trench 130, the stacked region is etched until the surface of the semiconductor substrate 100 is exposed.

After an insulating layer (not shown) is deposited on the resulting structure, a planarization process, such as an etch-back process or chemical mechanical polishing (CMP) process, is performed until the uppermost first epitaxial layers 111c and 115c of the first and second active patterns 111 and 115 are exposed. Consequently, a device isolation layer 135 is formed in the trench 135 to cover the first and second active patterns 111 and 115.

Referring to FIG. 3B, a photosensitive layer 11 is formed such that the second transistor region 105 is exposed. Using the photosensitive layer 11 as a mask, n⁻ dopant ions 147 and n⁺ dopant ions 148 are implanted into the second transistor region 105. The n⁻ dopant ions 147 are implanted at a relatively-high energy to form a second well 145 of n⁻-type conductivity in the substrate of the second transistor region 105, and the n⁺ dopant ions 148 are implanted at a relatively-low energy to form a second channel separation region 146 of n⁺-type conductivity on the second well 145 under the second active pattern 115.

Referring to FIG. 3C, after the photosensitive layer 11 is removed, a photosensitive layer 15 is formed such that the first transistor region 101 is exposed. Using the photosensitive layer 15 as a mask, p⁻ dopant ions 143 and p⁺ dopant ions 144 are implanted into the first transistor region 101. The p⁻ dopant ions 143 are implanted at a relatively-high energy to form a first well 141 of p⁻-type conductivity in the substrate of the first transistor region 105, and the p⁺ dopant ions 144 are implanted at a relatively-low energy to form a first channel separation region 142 of p⁺-type conductivity on the first well 141 under the first active pattern 111.

Alternatively, the second well 145 and the second channel separation region 146 may be formed in the second transistor region 105 after the first well 141 and the first channel separation region 142 are formed in the first transistor region 101.

Also, the n⁻ dopant ions 147 and the n⁺ dopant ions 148 may be implanted at different times.

Further, the p⁻ dopant ions 143 and the p⁺ dopant ions 144 are implanted into the first transistor region 101 at different times.

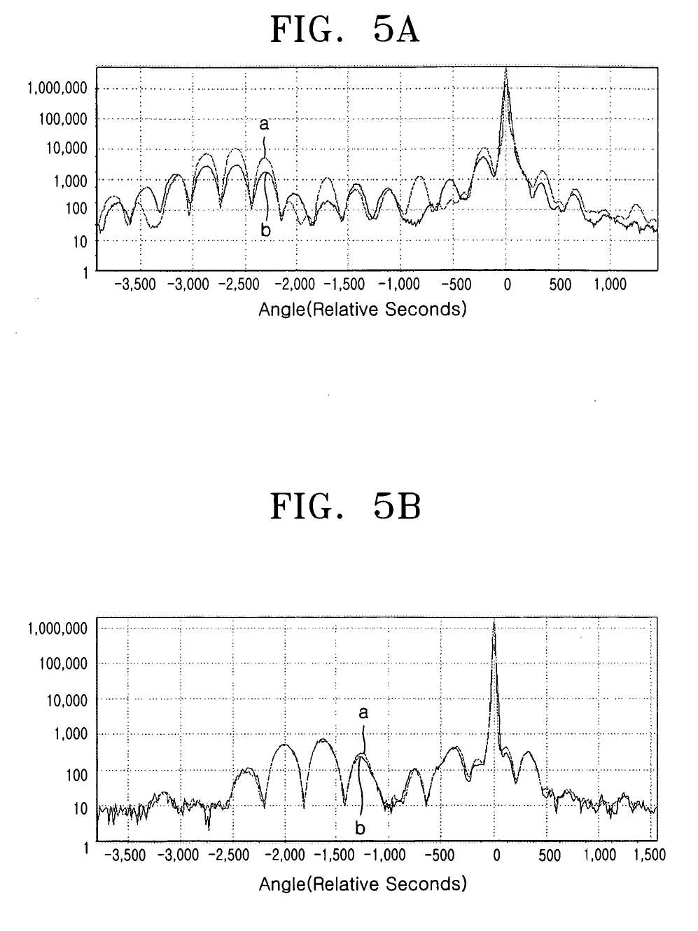

In one embodiment, the first and second active regions 111 and 115 are first formed, and then the first and second channel separation regions 142 and 146 are formed by the ion implantation. Accordingly, an excellent current characteristic of the CMOS transistor can be obtained as illustrated in FIG. 5B.

FIGS. 5A and 5B are respectively a characteristic curve of the CMOS transistor according to the present invention and a characteristic curve of a conventional CMOS transistor.

FIG. 5A illustrates the current characteristic of the conventional CMOS transistor that is manufactured through a method of forming active patterns after an ion implantation process for channel separation. The FIG. 5A shows that a great difference exists between a simulated current value “a” and a measured current value “b”. FIG. 5B illustrates the current characteristic of the CMOS transistor that is manufactured through a method of an ion implantation process for channel separation is performed after active patterns are formed. The FIG. 5A shows that little difference exists between a simulated current value “a” and a measured current value “b”. The reason for this is that a defect-free epitaxial layer can be formed because it is grown prior to the ion implantation process. Also, the diffusion of the implanted dopant ions due to a high-temperature prebake process performed before the growth of the epitaxial layer can be prevented, and thus a parasitic capacitance can be reduced.

Referring to FIGS. 3D and 4B, a pad oxide layer 151a, a nitride layer 151b, and a high density plasma (HDP) oxide layer 151c are sequentially formed on the first transistor region 101, and a pad oxide layer 155a, a nitride layer 155b, and an HDP oxide layer 155c are sequentially formed on the second transistor region 105. The HDP oxide layers 151c and 155c are dummy gate layers. The nitride layers 151b and 155b act as etch stop layers that prevent the first and second active patterns 111 and 115 being damaged during the patterning of the HDP oxide layers 151c and 155c. The pad oxide layers 151a and 155a act as stress buffer layers between the first and second active patterns 111 and 115 and the nitride layers 151b and 155b. The pad oxide layers 151a and 155a, the nitride layers 151b and 155b, and the HDP oxide layers 151c and 155c are etched to form a first dummy gate 151 and a second dummy gate 155. The first dummy gate 151 defines a gate region of the NMOS transistor, and includes a pad oxide layer 151a, a nitride layer 151b, and an HDP oxide layer 151c. Likewise, the second dummy gate 155 defines a gate region of the PMOS transistor, and includes a pad oxide layer 155a, a nitride layer 155b, and an HDP oxide layer 155c.

Referring to FIG. 3E, using the first and second dummy gates 151 and 155, the first and second active patterns 111 and 115 are etched until the first and second wells 141 and 145 are exposed, thereby forming a first etch region 162 and a second etch region 166. The first etch region 162 defines a region in which source/drain regions of the NMOS transistor are to be formed, and the second etch region 166 defines a region in which source/drain regions of the PMOS transistor are to be formed. The non-etched first active pattern acts as a first channel pattern 112 defining a channel region of the NMOS transistor, and the non-etched second active pattern acts as a second channel pattern 116 defining a channel region of the PMOS transistor.

Referring to FIG. 3F, through a selective epitaxial growth process, third epitaxial layers 161 and 165 are grown respectively in the first etch region 162 and the second etch region 166. The third epitaxial layers 161 and 165 have a different etch selectivity from that of the first epitaxial layer 111a, 111b, 111c, 115a, 115b and 115c. The third epitaxial layers 161 and 165 are formed of monocrystalline silicon, that is, the same material as the second epitaxial layer 121a, 121b, 125a and 125b. By a tilted implantation process, n⁺ dopant ions are implanted into the third epitaxial layer 161 to form source/drain regions of the NMOS transistor, and p⁺ dopant ions are implanted into the third epitaxial layer 165 to form source/drain regions of the PMOS transistor.

As describe above, the first and second active patterns 111 and 115 are etched until the semiconductor substrate 100 is exposed, and then first and second source/drain regions are formed. Accordingly, the heavily-doped channel separation regions 142 and 146 are respectively formed under the first and second source/drain regions 161 and 165, thereby preventing a parasitic capacitance.

Referring to FIG. 3G, an insulating layer 170 which is a nitride layer, is deposited and is then etched by an etch-back process or a CMP process until the first and second dummy gates 151 and 155 are exposed. In the subsequent process, the insulating layer 170 acts as a mask pattern.

Referring to FIGS. 3H and 4C, the HDP oxide layers 151c and 155c are etched and removed using the insulating layer 170 as a mask. Thereafter, the nitride layers 151b and 155b and the pad oxide layers 151a and 155a are removed to form a first gate trench 192 and a second gate trench 196. The nitride layers 151b and 155b prevent the first and second channel patterns 112 and 116 from being damaged during the etching of the HDP oxide layers 151c and 155c.

At this point, the first channel pattern 112, the second channel pattern 116, and the device isolation layer 135 are partially exposed through the first and second gate trenches 192 and 196. When the second epitaxial layers 121a and 121b of the first channel pattern 112 and the second epitaxial layers 125a and 125b of the second channel pattern 116 are not doped with dopants, channel ions can be implanted into the first and second channel patterns 112 and 116 through the exposed first and second gate trenches 192 and 196 after the forming of the first and second gate trenches 192 and 196.

Referring to FIGS. 31 and 4D, using the insulating layer 170 as a mask, the exposed device isolation layer 135 is etched and removed to expose the side surfaces of the first and second channel patterns 112 and 116. At this point, the device isolation layer 135 is etched until the surface of the substrate 100 is exposed. A reference numeral 193 denotes a third etch region from which the device isolation layer 135 of the first transistor region 101 is removed, and a reference numeral 197 denotes a fourth etch region from which the device isolation layer 135 of the second transistor region 105 is removed. Accordingly, the first epitaxial layers 111a, 111b and 111c and the second epitaxial layers 121a and 121b of the first channel pattern 112 are exposed through the third etch region 193, and the first epitaxial layers 115a, 115b and 115c and the second epitaxial layers 125a and 125b of the second channel pattern 116 are exposed through the fourth etch region 197.

Referring to FIGS. 3J and 4E, the first epitaxial layers 111a, 111b and 111c and the first epitaxial layers 115a, 115b and 115c are selectively etched and removed by Isotropic etching. Accordingly, a plurality of first tunnels 111a′ and 111b′ are formed in a region from which the first epitaxial layers 111a and 111b are removed, and a tunnel-shaped first groove 111c′ is formed in a region from which the uppermost epitaxial layer 111c is removed. Likewise, a plurality of second tunnels 115a′ and 115b′ are formed in a region from which the first epitaxial layers 115a and 115b are removed, and a tunnel-shaped second groove 115c′ is formed in a region from which the uppermost epitaxial layer 115c is removed. The unremoved second epitaxial layers 121a and 121b act as a plurality of channel layers constituting the channel region 121 of the NMOS transistor. Similarly, the unremoved second epitaxial layers 125a and 125b act as a plurality of channel layers constituting the channel region 125 of the PMOS transistor.

Referring to FIGS. 3K and 4F, a first gate insulating layer 181 of the NMOS transistor is formed on inner surfaces of the first tunnels 111a′ and 111b′ and the first groove 111c′, and a second gate insulating layer 185 of the PMOS transistor is formed on inner surfaces of the second tunnels 115a′ and 115b′ and the second groove 115c′. The first and second gate insulating layers 181 and 185 may be formed by thermally oxidizing the second epitaxial layers 121a, 121b, 125a and 125b, or may be conformally formed by deposition. The first and second gate insulating layer 181 and 185 each include a silicon oxide layer, a silicon oxynitride layer, or a silicon nitride layer.

Referring to FIGS. 3L and 4G, through a damascene process, a first gate 191 of the NMOS transistor is formed in the third etch region 193 to cover the channel layers 121a and 121b, and a second gate 195 of the PMOS transistor is formed in the fourth etch region 197 to cover the channel layers 125a and 125b. That is, a doped polysilicon layer is deposited to bury the first tunnels 111a′ and 111b′, and the first groove 111c′, the second tunnels 115a′ and 115b′, and the second groove 115c′, and then a planarization process, such as an etch-back process or a CMP process, is performed until the gate insulating layer 170 is exposed. At this point, in order to reduce a gate resistance, a metal suicide layer may be formed on the polysilicon layer, or a gate cap layer acting as an insulating layer, such as an oxide layer or a nitride layer, may be formed on the first and second gates 191 and 195.

Thereafter, the insulating layer 170 is removed to complete the vertical CMOS transistor illustrated in FIGS. 2A and 2B. Although not shown in the drawings, metal lines are formed for the subsequent processes.

As described above, the ion implantation process for forming the channel separation regions is performed after the forming of the active patterns, and thus the defect-free epitaxial layers can be grown, thereby improving the device characteristics. Also, the active patterns can be used as an alignment key for the ion implantation, and thus a mask process for forming a separate alignment key can be omitted, thereby simplifying the manufacturing process.

In addition, the ion implantation processes for forming the channel separation regions and the wells are simultaneously performed, and thus the manufacturing process can be simplified. Also, since the ion implantation process for the channel separation is performed after the growth of the epitaxial layers, it is possible to prevent the implanted dopant ions from being diffused by a high-temperature prebake process performed before the growth of the epitaxial layer.

Further, the channel layers are vertically stacked on the semiconductor substrate in the vertical NMOS transistor. Accordingly, the occupation areas of the channel and source/drain regions can be decreased, thereby improving the integration degree of the device. Also, the parasitic capacitance can be reduced, thereby improving the operating speed of the transistor.

Moreover, the first and second epitaxial layers are etched to form the active patterns of the PMOS and NMOS transistors, and then the dopant ions are implanted into the substrate to form the channel separation regions of the PMOS and NMOS transistors. Accordingly, it is possible to obtain the excellent current characteristic of the transistor. Also, the region in which the source/drain epitaxial layers are formed is defined by etching the active patterns until the surface of the substrate is exposed. Accordingly, the dopants implanted into the epitaxial layer can be prevented from diffusing into the lower portion of the channel region.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method for manufacturing a semiconductor device, comprising:
alternately stacking a sacrificial layer and a channel layer on a semiconductor substrate;
etching the sacrificial layer and the channel layer to form a separated active pattern;
forming a device isolation layer to cover sidewalls of the active pattern;
implanting dopant ions into the entire semiconductor substrate, thereby forming a channel separation region under the active pattern;
etching a portion of the active pattern to separate the active pattern from a pair of facing sidewalls of the device separation layer, thereby forming a channel pattern having a pair of first exposed sidewalls;
forming source/drain semiconductor layers on the first sidewalls of the channel pattern;
removing a part of the device isolation layer to expose a pair of second sidewalls of the channel pattern contacting with the device separation layer;
removing the sacrificial layer included in the channel pattern; and
forming a conductive layer for a gate electrode to cover the channel layer exposed by the removing of the sacrificial layer.

2. The method of claim 1, wherein the channel layer includes the same material as the semiconductor substrate, and the sacrificial layer has a different etch selectivity than that of the channel layer.

3. The method of claim 2, wherein the channel layer includes an epitaxially-grown monocrystalline silicon layer, and the sacrificial layer includes an epitaxially-grown monocrystalline germanium layer or an epitaxially-grown monocrystalline silicon-germanium layer.

4. The method of claim 1, wherein high-concentration dopant ions are implanted to further form a well during the forming of the channel separation region, the high-concentration dopants having the same conductivity type as the dopant ions implanted into the channel separation region.

5. The method of claim 1, wherein the source/drain semiconductor layer includes a monocrystalline silicon layer formed through a selective epitaxial process.

6. The method of claim 1, wherein the active pattern is etched during the forming of the channel pattern until a surface of the semiconductor substrate is exposed, and the device isolation layer is etched during the removing of a part of the device isolation layer until a surface of the semiconductor substrate is exposed.

7. A method for manufacturing a semiconductor device, comprising:
forming a first active pattern and a second active pattern on a semiconductor substrate, the first active pattern being separately formed and including a first sacrificial layer and a first channel layer that are alternately stacked, the second active pattern being separately formed and including a second sacrificial layer and a second channel layer that are alternately stacked;
forming a device isolation layer to cover sidewalls of the first active pattern and sidewalls of the second active pattern;
implanting dopant ions into the entire semiconductor substrate, thereby forming a first channel separation region and a first well under the first active pattern and forming a second channel separation region and a second well under the second active pattern;
etching a portion of the first active pattern and a portion of the second pattern to separate the first and second active patterns from a pair of corresponding sidewalls of the device separation layer, thereby forming a first channel pattern having a pair of first exposed sidewalls and a second channel pattern having a pair of first exposed sidewalls;
forming first source/drain semiconductor layers on the first sidewalls of the first channel pattern and forming second source/drain semiconductor layers on the first sidewalls of the second channel pattern;
removing a part of the device isolation layer to expose a pair of second sidewalls of the first channel pattern and a pair of second sidewalls of the second channel pattern contacting with another pair of corresponding sidewalls of the device separation layer;
removing the first and second sacrificial layers; and
forming a first conductive layer for a gate electrode to cover the first channel layer exposed by the removing of the first sacrificial layer, and forming a second conductive layer for a gate electrode to cover the second channel layer exposed by the removing of the second sacrificial layer.

8. The method of claim 7, wherein the first and second channel layers include the same material as the semiconductor substrate, and the first and second sacrificial layers have a different etch selectivity than that of the first and second channel layers.

9. The method of claim 8, wherein the first and second channel layers each includes an epitaxially-grown monocrystalline silicon layer, and the first and second sacrificial layers each include an epitaxially-grown monocrystalline germanium layer or an epitaxially-grown monocrystalline silicon-germanium layer.

10. The method of claim 7, wherein the forming of the first and second channel separation regions and the first and second well comprises:
forming a first photosensitive layer on the semiconductor substrate so that the first active pattern is exposed;
implanting high-concentration dopant ions of a first conductivity type and low-concentration dopant ions of the first conductivity type into the semiconductor substrate by using the first photosensitive layer, thereby forming the first channel separation region and the first well under the first active pattern;
forming a second photosensitive layer on the semiconductor substrate so that the second active pattern is exposed; and
implanting high-concentration dopant ions of a second conductivity type and low-concentration dopant ions of the second conductivity type into the semiconductor substrate by using the second photosensitive layer, thereby forming the second channel separation region and the second well under the second active pattern.

11. The method of claim 10, wherein the high-concentration dopant ions of the first conductivity type are implanted at a predetermined energy and the low-concentration dopant ions of the first conductivity type are implanted at an energy higher than the predetermined energy, thereby forming the first well of low concentration and forming the first channel separation region of high concentration on the first well.

12. The method of claim 10, wherein the high-concentration dopant ions of the second conductivity type are implanted at a predetermined energy and the low-concentration dopant ions of the second conductivity type are implanted at an energy higher than the predetermined energy, thereby forming the second well of low concentration and forming the second channel separation region of high concentration on the second well.

13. The method of claim 7, further comprising before the forming of the first and second channel patterns,
forming a first dummy gate and a second dummy gate on the first active pattern and the second active pattern, respectively, the first and second dummy gate each having a pad oxide layer, a nitride layer, and a high density plasma oxide layer stacked therein,
wherein the first active pattern and the second active pattern are etched by using the first dummy gate as a mask for the first active pattern and using the second dummy gate as a mask for the second active pattern, thereby forming the first channel pattern and the second channel pattern.

14. The method of claim 13, wherein the etching of the first active pattern and the second active pattern for forming the first channel pattern and the second channel pattern is performed until a surface of the semiconductor substrate is exposed.

15. The method of claim 13, further comprising before the removing of a part of the device isolation layer;
forming an insulating layer on the semiconductor substrate to cover the first and second dummy gates;
planarizing the insulating layer until the first and second dummy gates are exposed; and
removing the first and second gates to expose the device separation layer contacting with a pair of the second sides walls of the first and second channel patterns,
wherein the exposed device separation layer is etched by using the insulating layer as a mask until the semiconductor substrate is exposed.

16. The method of claim 15, wherein the insulating layer is a nitride layer.

17. The method of claim 7, wherein the first and second source/drain semiconductor layers includes the same material as the first and second channel layers.

18. The method of claim 7, wherein the forming of the first and second source/drain semiconductor layers comprises:
forming a first monocrystalline silicon layer on the first sidewalls of the first channel patterns and forming a second monocrystalline silicon layer on the first sidewalls of the second channel pattern by a selective epitaxial process; and
implanting dopant ions of the second conductivity type and dopant ions of the first conductivity type into the first monocrystalline silicon layer and the second monocrystalline silicon layer, respectively.

19. The method of claim 7, further comprising before the first and second conductive layers:
forming a first gate insulating layer between the first conductive layer and the first channel layer; and
forming a second gate insulating layer between the second conductive layer and the second channel layer.

20. The method of claim 7, wherein the first channel separation region is formed on the first well under the first channel layer and the first source/drain semiconductor layer, and the second channel separation region is formed on the second well under the second channel layer and the second source/drain semiconductor layer.

21. A semiconductor device comprising:
a semiconductor substrate including a first well and a second well;
a first channel region including a plurality of first channel layers separately stacked on the first well in a vertical direction with respect to a surface of the semiconductor substrate and a plurality of first tunnels disposed between the first channel layers, and a second channel region including a plurality of second channel layers separately stacked on the second well in a vertical direction with respect to the surface of the semiconductor substrate and a plurality of second tunnels disposed between the second channel layers;
first source/drain regions formed on the first well in such a way as to contact with a pair of first facing sidewalls of the first channel layers, and second source/drain regions formed on the second well in such a way as to contact with a pair of first facing sidewalls of the second channel layers;
a first gate electrode buried in the first tunnels and formed in a direction crossing a pair of second facing sidewalls of the first channel layers to cover the first channel layers, and a second gate electrode buried in the second tunnels and formed in a direction crossing a pair of second facing sidewalls of the second channel layers to cover the second channel layers;
a first gate insulating layer formed between the first gate electrode and the first channel layers, and a second gate insulating layer formed between the second gate electrode and the second channel layers; and
a first channel separation region formed on the first well under the first channel region and the first source/drain regions, and a second channel separation region formed on the second well under the second channel region and the second source/drain regions.

22. The semiconductor device of claim 21, wherein the first channel separation region is a high-concentration dopant region having the same conductivity type as the first well, and the second channel separation region is a high-concentration dopant region having the same conductivity type as the second well, the first channel separation region having a conductivity type opposite to that of the second channel separation region.

23. The semiconductor device of claim 21, wherein the first source/drain regions and the second source/drain regions include the same material as the first and second channel layers.

24. The semiconductor device of claim 23, wherein the first and second source/drain regions and the first and second channel layers include an epitaxially-grown monocrystalline silicon layer.

25. The semiconductor device of claim 21, further comprising a device isolation layer formed to cover the first and second source/drain regions except for the first and second channel regions.

26. The semiconductor device of claim 21, wherein the first and second channel regions and the first and second source/drain regions are formed in the same plane on the semiconductor substrate.
